(19) United States
(12) Patent Application Publication
(10) Pub. No.: US 2005/0245069 A1
(43) Pub. Date: Nov. 3, 2005

(54) Substrate flattening method

(75) Inventor: Daniel R. Shepard, Salem, NH (US)

Correspondence Address: Daniel R. Shepard;Contour Semiconductor, Inc., Suite 104, 93 Stiles Road, Salem, NH, 03079, US

(73) Assignee: Contour Semiconductor, Inc.

(21) Appl. No.: 11/117,118

(22) Filed: Apr. 28, 2005

Related U.S. Application Data
(60) Provisional application No. 60/565,962, filed on Apr. 28, 2004.

(51) Int. Cl. H01L 21/4763

(52) U.S. Cl. 438/626

(57) ABSTRACT

The present invention relates to the manufacture and processing of semiconductor wafers, and more particularly to methods for keeping the surface of a wafer flat during processing to improve lithography, planarization, and other process steps that benefit from a flatter wafer. The present invention is a means to disrupt the long-range stress across the surface of a wafer made of crystalline silicon or other materials so as to prevent distortions such as dishing of that wafer. To prevent such dishing or similar distortions, the long-range continuity of the film must be disrupted. The long-range continuity of the film can be disrupted simply by etching channels in the surface of the wafer. These etched channels could be incorporated into or combined with registration marks that might be etched initially on the wafer for the purpose of enabling a step and repeat lithography exposure tool to find each exposure point. To prevent long-range continuous films in the channels from having an effect, features in the channels at the intersections of horizontal and vertical channels can be incorporated to disrupt the continuous films therein.

### CROSS REFERENCE TO RELATED APPLICATIONS

This application claims the benefits of U.S. Provisional Application No. 60/565,962, filed on Apr. 28, 2004, and that document in its entirety is hereby incorporated herein by reference; this application references U.S. Pat. No. 6,586,327 and that patent is included herein in its entirety by reference.

### FIELD OF THE INVENTION

The present invention relates to the manufacture and processing of semiconductor wafers, and more particularly to methods for keeping the surface of a wafer flat during processing to improve lithography, planarization, and other process steps that benefit from a flatter wafer.

### REFERENCE TO A SEQUENCE LISTING, A TABLE, OR A COMPUTER PROGRAM LISTING COMPACT DISK APPENDIX

Not Applicable.

### REFERENCE REGARDING FEDERAL SPONSORSHIP

Not Applicable.

### STATEMENT REGARDING FEDERALLY SPONSORED RESEARCH OR DEVELOPMENT

Not Applicable.

### SUMMARY OF THE INVENTION

Semiconductor manufacturing is typically performed on the flat surface of a substrate such as a crystalline silicon wafer, quartz wafer, glass or the like. In some cases, other substrates such as plastic—either in wafers, continuous sheets, or other shapes—may be utilized. Very often during processing, thin films of materials will be deposited that will result with stresses within the films. These stresses can cause distortions within the flatness of the underlying substrate. A well known example is the bimetallic strip wherein a metal strip is made having one side of one material and the other side of a different material with different properties such that when the strip is heated the strip curls due to the differences of thermal expansion of the two materials (thermostats were made from this device for many years).

Likewise, a circular crystalline silicon wafer will often become slightly saucer shaped because the distortion typically occurs about equally in two dimensions (but it may take on a potato chip shape). This saucer shape will adversely affect subsequent processing steps such as Chemical Mechanical Polishing (CMP), lithographic exposures, to name a few. For example, during lithographic exposures, a downwardly dished wafer might be closer to the exposure source at the center of the wafer than it is at the edges resulting in focusing errors for which corrections would have to be made. For example, during a CMP process step, the edges of the wafer might polish more quickly than the center due to a raised edge resulting from upward dishing. It should be noted that the pliability of the polishing pad during a CMP process step and the depth of focus during a lithography step, will allow for a small degree of correction for surface non-flatness, but not to the degree that can be seen with a long-range, wafer wide, stress-induced distortion of the wafer's flatness. With the present invention, there may be a very slight distortion of the surface flatness within the area delineated by the channels, but this distortion is believed to be within the range of what is correctable by the pliability of the polishing pad.

The present invention is a method of processing a substrate such that stresses that might occur during certain processing steps will not be able to cause this long-range distortion across the wafer.

### BRIEF DESCRIPTION OF THE DRAWINGS

FIG. 1 illustrates an edge view of a normal flat wafer both with a stress-induced distortion.

FIG. 2 illustrates an edge view of a wafer having a stress-induced distortion.

FIG. 3 illustrates a pattern on the wafer surface to disrupt long-range stresses that might otherwise induce distortions.

FIG. 4 illustrates enhancements to the intersections of vertical and horizontal canals.

### DESCRIPTION OF THE PREFERRED EMBODIMENT

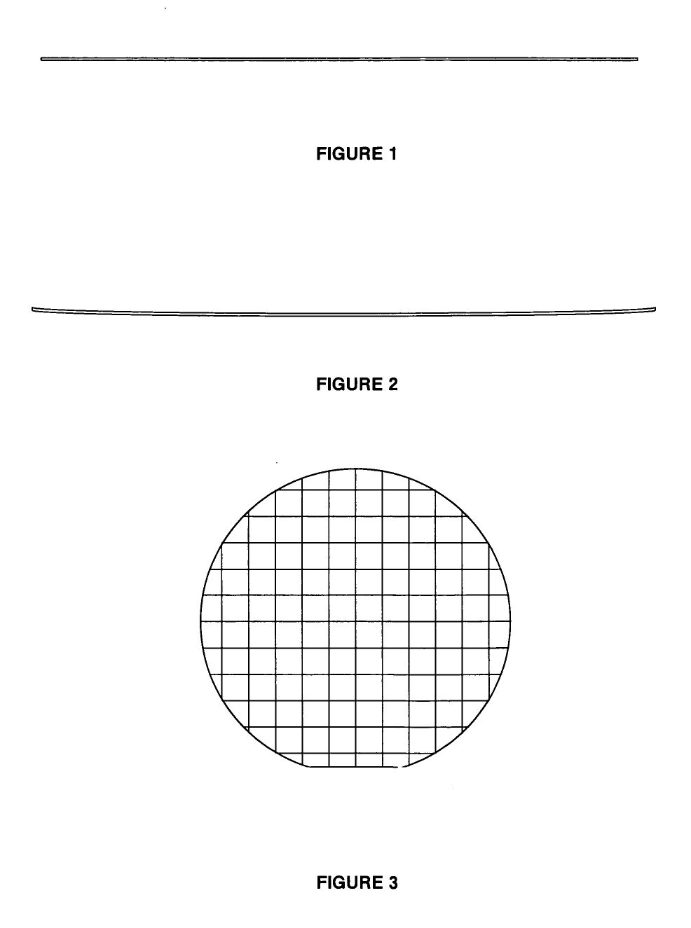

The present invention is a means to disrupt the long-range stress across the surface of a wafer made of crystalline silicon or other materials so as to prevent distortions and warping such as dishing of that wafer. As shown in edgewise view in FIG. 1, a wafer or other substrate is typically flat. It is believed that the deposition of a continuous film or stack of films across the surface of the wafer may cause dishing or warping of the wafer because of the shrinkage of that film relative to the width and height of the wafer as shown in FIG. 2 in edgewise view. To prevent such dishing or similar distortions, the long-range continuity of the film can be disrupted.

The long-range continuity of the film can be disrupted simply by etching channels in the surface of the wafer as shown in FIG. 3. These channels might correspond to the dicing channels required for cutting the wafer into individual die following processing. The necessary depth of the channels is believed to be at least equal to the thickness of the thickest deposited film and, preferably, twice the thickness of the deposited film stack, but such depth—either greater or lesser—can be determined empirically. These etched channels could be incorporated into or combined with registration marks that might be etched initially on the wafer for the purpose of enabling a step and repeat lithography exposure tool to find each exposure point, the channels being etched at any point prior to the deposition of the film that is believed will cause a warping stress.

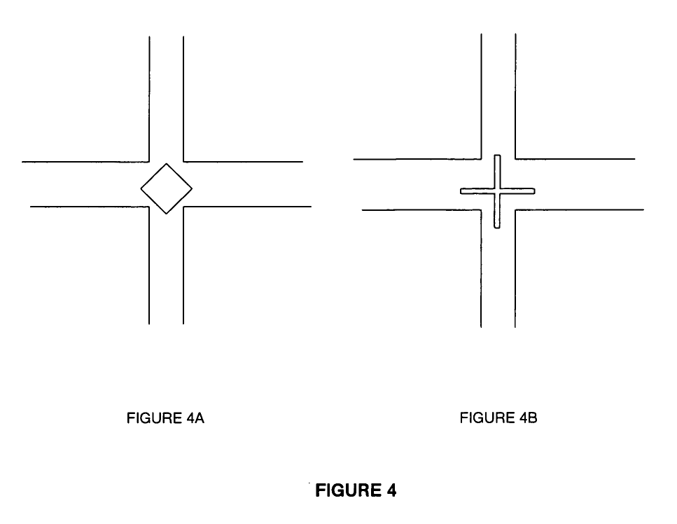

Furthermore, this depth may also be a function of the pitch of the channels. If the individual die are small, the cumulative stress of the film along the length of the individual channels may cause sufficient stress to induce a degree of dishing. To prevent long-range continuous films in the channels from having an effect, intersection features in the channels at the intersections of horizontal and vertical channels can be incorporated to disrupt the continuous films therein. FIG. 4 shows two such possibilities of raised features (features not etched away when the channels are etched) to cause this disruption to the film as a close-up at the point of intersection of a vertical channel with a horizontal channel. This raised feature is structured such that the film cannot form a continuous and direct path across the substrate within the channels.

A variation would be to partially cut the dicing channels with a circular dicing saw or etch the channels with a focused ion beam miller or other cutting or etching means. Another variation might be to utilize the present invention to control the degree of dishing rather than to completely eliminate the dishing and may be useful in certain MEMS applications or other applications such as the creation of a mirrored surface having a desired focal length that one might determine by controlling the degree of dishing.

Another variation may occur when a substrate is processed with a topology based lithographic process as is disclosed in U.S. Pat. No. 6,586,327. In that process, as is disclosed in that patent, the substrate is prepared by applying contouring comprising differing depth rows and columns to the surface of that substrate. The substrate is then processed with a series of film depositions, planarizations and etches (or other material removal techniques) iteratively. The applied contouring will provide some degree of long range film stress disruption. In accordance with the present invention, to better disrupt this long range film stress, the contouring would be as close to continuous edge-to-edge across the entire substrate as practical. Dummy features between contoured die pattern could be added to maintain the disruption in addition to or instead of the dicing channel features and intersection features. This technique to disrupt the stresses in a deposited film will also help to prevent the cracking and pealing of deposited films.

The foregoing description of an example of the preferred embodiment of the invention and the variations thereon have been presented for the purposes of illustration and description. It is not intended to be exhaustive or to limit the invention to the precise forms disclosed. Many modifications and variations are possible in light of the above teaching. It is intended that the scope of the invention be limited not by this detailed description.

1. A method for disrupting the stress in a film deposited on a substrate, the method comprising applying a contoured surface to the wafer prior to depositing said film.

2. The method of claim 1 whereby said film consists of a single layer of materials.

3. The method of claim 1 whereby said film consists of multiple layers of materials.

4. The method of claim 1 whereby said contoured surface comprises channels that run between die being fabricated upon said substrate.

5. The method of claim 1 whereby said contoured surface comprises recesses within the area of the die being fabricated upon said substrate.

6. A method for reducing the warping of a substrate following the deposition of a film on said substrate, the method comprising applying a contoured surface to the wafer prior to depositing said film.

7. The method of claim 6 whereby said film consists of a single layer of materials.

8. The method of claim 6 whereby said film consists of multiple layers of materials.

9. The method of claim 6 whereby said contoured surface comprises channels that run between die being fabricated upon said substrate.

10. The method of claim 6 whereby said contoured surface comprises recesses within the area of the die being fabricated upon said substrate.
